(19) United States
(12) Patent Application Publication
(10) Pub. No.: US 2018/0131156 A1
(43) Pub. Date: May 10, 2018

(54) PHOTOELECTRIC CONVERSION ELEMENT AND OPTICAL COMMUNICATION MODULE

(71) Applicant: Murata Manufacturing Co., Ltd., Nagaokakyo-shi (JP)

(72) Inventors: Masashi Yanagase, Nagaokakyo-shi (JP); Keiji Iwata, Nagaokakyo-shi (JP)

(21) Appl. No.: 15/865,761

(22) Filed: Jan. 9, 2018

Related U.S. Application Data
(63) Continuation of application No. PCT/JP2016/072891, filed on Aug. 4, 2016.

(30) Foreign Application Priority Data
Aug. 12, 2015 (JP) 2015-159292

(51) Int. Cl. H01S 5/042; H01S 5/02; H01S 5/022; G02B 6/42; H01L 31/0203; H01L 31/02; H01L 31/0232; H01L 31/0304; H01L 25/16; H01L 29/866; H01L 27/02

(52) U.S. Cl. CPC H01S 5/0425; H01S 5/0206; H01S 5/02208; G02B 6/4239; G02B 6/4242; H01L 31/0203; H01S 5/183; H01L 31/02325; H01L 31/0304; H01L 25/167; H01L 29/866; H01L 27/0248; H01L 31/02005

(57) ABSTRACT

A surface emitting element including a semiconductor substrate and a casing. The substrate includes an optical element having a photoelectric conversion function. First and second terminal electrodes are disposed on the substrate. The casing has a depression for accommodating the substrate. Moreover, first and second connection electrodes are formed in the casing. The first and second terminal electrodes are formed so as to protrude from the side surfaces of the substrate. The first and second connection electrodes are formed so as to protrude toward the depression side in the casing. The first terminal electrode and the first connection electrode are in contact with each other, and the second terminal electrode and the second connection electrode are in contact with each other.

### CROSS REFERENCE TO RELATED APPLICATIONS

The present application is a continuation of PCT/JP2016/072891 filed Aug. 4, 2016, which claims priority to Japanese Patent Application No. 2015-159292, filed Aug. 12, 2015, the entire contents of each of which are incorporated herein by reference.

### TECHNICAL FIELD

The present disclosure relates to a photoelectric conversion element such as a surface emitting element or a photodiode.

### BACKGROUND

There have currently been devised a variety of surface emitting elements such as a VCSEL (Vertical Cavity Surface Emitting Laser) and optical communication systems combining photodiodes and optical fibers. In an optical communication system described in Patent Document 1, a surface emitting element and an optical fiber are coupled by a direct coupling system. Specifically, one end of the optical fiber is brought close to a light-emitting surface of the surface emitting element, and the light emitted from the surface emitting element is directly incident on the optical fiber.

In order to achieve this system, the optical communication system described in Patent Document 1 includes a surface emitting element, a silicon interposer, and an optical fiber. The optical fiber is fixed to a through hole formed in the silicon interposer.

The surface emitting element is mounted on the silicon interposer. The light-emitting surface of the surface emitting element faces the silicon interposer. With this configuration, a mounting bump is formed on the light-emitting surface side of the surface emitting element. The surface emitting element is bonded to the silicon interposer by this mounting bump.

FIG. 13(A) is a plan view showing a placement relationship between a conventional surface emitting element and optical fiber, and FIG. 13(B) is a cross sectional view taken along line E-E′ shown in FIG. 13(A).

The conventional surface emitting element 10P includes a substrate 21P, a first electrode 22P, a second electrode 23P, and mounting bump electrodes 241P, 242P, 243P. The substrate 21P is mainly made of GaAs and has a structure of a vertical cavity surface emitting laser (VCSEL) although a specific configuration is not shown. Light resonated inside the substrate 21P is output to the outside from an emitting portion at the center of the surface of the substrate 21P.

The first electrode 22P, the second electrode 23P, and the mounting bump electrodes 241P, 242P, 243P are formed on the surface of the substrate 21P. The first electrode 22P and the second electrode 23P are disposed in a center region of the surface of the substrate 21P so as to surround the emitting portion. The bump electrodes 241P, 242P and the two bump electrodes 243P are disposed respectively at four corners of the surface of the substrate 21P. The bump electrode 241P and the bump electrode 242P are disposed at diagonal positions. The first electrode 22P is connected to the bump electrode 241P, and the second electrode 23P is connected to the bump electrode 242P.

An optical fiber 90 is disposed close to the light-emitting surface of the substrate 21P.

Patent Document 1: Japanese Patent Application Laid-Open No. 2015-22247.

In the conventional configuration, in order to bring the optical fiber 90 close, the bump electrodes 241P, 242P, 243P need to be disposed at a longer distance than a radius of the optical fiber 90 from the center of the surface of the substrate 21P. Since the bump electrodes 241P, 242P, 243P are disposed on the surface of the substrate 21P, a region corresponding to diameters of the bump electrodes 241P, 242P, 243P is required on the surface of the substrate 21P.

Hence in the conventional configuration, at least a sum of the diameter of the optical fiber 90 and the diameters of the two bump electrodes 241P, 242P is required as the minimum length of the diagonal line of the surface of the substrate 21P. For this reason, reduction in size of the substrate 21P has not been easy so far, and reduction in cost of the surface emitting element 10P has not been easy.

### SUMMARY OF THE INVENTION

It is an object of the present disclosure to provide an inexpensive photoelectric conversion element without causing degradation of performance.

Thus, a photoelectric conversion element is disclosed that includes a semiconductor substrate with an optical element having a photoelectric conversion function and a first and second terminal electrodes disposed on the substrate. The optical conversion element includes a casing having a depression for accommodating the substrate, and a first connection electrode and a second connection electrode that are formed in the casing. The first terminal electrode and the second terminal electrode are formed so as to protrude from side surfaces of the substrate. The first connection electrode and the second connection electrode are formed so as to protrude toward the depression in the casing. The first terminal electrode and the first connection electrode are in contact with each other, and the second terminal electrode and the second connection electrode are in contact with each other.

In one exemplary configuration, a member having a photoelectric conversion function and a member connecting this member to an external circuit are made of different materials. Therefore, the member of the photoelectric conversion function becomes small without causing deterioration in photoelectric conversion function.

In the photoelectric conversion element of the present disclosure, the substrate is preferably made of GaAs mainly, and the casing is mainly made of silicon.

With this configuration, it is possible to facilitate configuration of a high-performance and inexpensive photoelectric conversion element.

In the photoelectric conversion element of the present disclosure, it is preferable that the depression be a through hole penetrating from a front surface to a rear surface of the casing.

With this configuration, it is easy to process the depression, and the substrate can be mounted on the casing in a stable posture.

Further, in an exemplary aspect of the photoelectric conversion element of the present disclosure, the depression has a tapered shape in which a planar area decreases from an opening surface toward a bottom surface. A planar shape of the bottom surface is identical to a planar shape of the substrate.

With this configuration, when the substrate is inserted into the depression, the substrate is disposed at an appropriate position of the depression in an appropriate posture by the tapered shape of the depression.

In the photoelectric conversion element of the present disclosure, a depth of the depression is larger than a thickness of the substrate.

With this configuration, even if the optical fiber comes into contact with the surface of the photoelectric conversion element, it does not come into contact with the substrate and, thus, prevents damage to the substrate.

In the photoelectric conversion element of the present disclosure, the substrate is rectangular in a plan view, and the first terminal electrode and the second terminal electrode are formed so as to protrude only from side surfaces of the substrate which face each other.

With this configuration, it is possible to further reduce the area of the substrate in a plan view.

Further, the photoelectric conversion element of the present disclosure may include the substrate having a rectangular shape in a plan view. Moreover, a third terminal electrode can be provided that is different from the first terminal electrode and the second terminal electrode. The first terminal electrode, the second terminal electrode, and the third terminal electrode are disposed respectively at four corners of the surface of the substrate.

With this configuration, the substrate is stably supported and fixed to the casing.

Further, in one exemplary aspect, two each of the first terminal electrode and the second terminal electrode are provided. The first terminal electrodes are disposed with rotational symmetry by 180°, and the second terminal electrodes are disposed with rotational symmetry by 180°, in a plan view of the substrate.

With this configuration, whichever of the two modes in which the substrate is rotated by 180°, it is properly mounted on the casing. This facilitates mounting of the substrate on the casing.

In the photoelectric conversion element of the present disclosure, a Zener diode connected between the first external electrode and the second external electrode is formed in the casing.

With this configuration, it is possible to protect the substrate from external static electricity without increasing its shape.

In another exemplary aspect, an optical communication module can include any one of the photoelectric conversion elements described above, an optical fiber, and a fiber fixing member. One end of a light guide path of the optical fiber is disposed close to a surface of the substrate. The fiber fixing member includes a through hole, through which the optical fiber is inserted, and fixes the optical fiber. The fiber fixing member and the photoelectric conversion element are bonded to each other.

With this configuration, it is possible to achieve a high-performance and compact optical communication module.

Further, in the optical communication module of the exemplary aspect, a size of a plane of the substrate is smaller than a diameter of the optical fiber.

With this configuration, the substrate becomes small, and an inexpensive optical communication module can be achieved.

According to the present disclosure, it is possible to achieve a high-performance and inexpensive photoelectric conversion element.

### BRIEF DESCRIPTION OF THE DRAWINGS

FIG. 1(A) is a plan view of a surface emitting element according to a first exemplary embodiment, and FIG. 1(B) is a side sectional view of the surface emitting element according to the first exemplary embodiment.

FIG. 2(A) is a plan view of a substrate of the surface emitting element according to the first exemplary embodiment, and FIG. 2(B) is a sectional view of the substrate of the surface emitting element according to the first exemplary embodiment.

FIG. 3 is a plan view of a substrate of a surface emitting element according to a second exemplary embodiment.

FIG. 4(A) is a plan view of a surface emitting element according to a third exemplary embodiment, and FIG. 4(B) is a side sectional view of the surface emitting element according to the third exemplary embodiment.

FIG. 5 is a plan view of a substrate of a surface emitting element according to a fourth exemplary embodiment.

FIG. 6 is a side sectional view of a surface emitting element according to a fifth exemplary embodiment.

FIG. 7 is a side sectional view of a surface emitting element according to a sixth exemplary embodiment.

FIG. 8 is a side sectional view of a surface emitting element according to a seventh exemplary embodiment.

FIG. 9 is a side sectional view of a surface emitting element according to an eighth exemplary embodiment.

FIG. 10 is a plan view of a surface emitting element according to a ninth exemplary embodiment.

FIG. 11 is a side sectional view of a surface emitting element according to a tenth exemplary embodiment.

FIG. 12 is a side sectional view of an optical communication module according to an eleventh exemplary embodiment.

FIG. 13(A) is a plan view showing a placement relationship between a conventional surface emitting element and optical fiber, and FIG. 13(B) is a sectional view taken along line E-E′ shown in FIG. 13(A).

### DETAILED DESCRIPTION

In each of the following embodiments, a surface emitting element such as a vertical cavity surface emitting laser (VCSEL) will be exemplified as a photoelectric conversion element, but the following configuration is also applicable to a light-receiving element such as a photodiode.

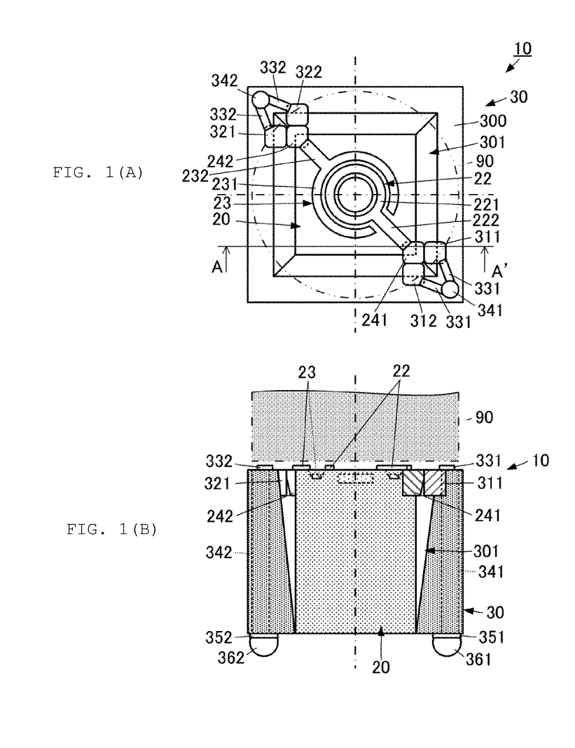

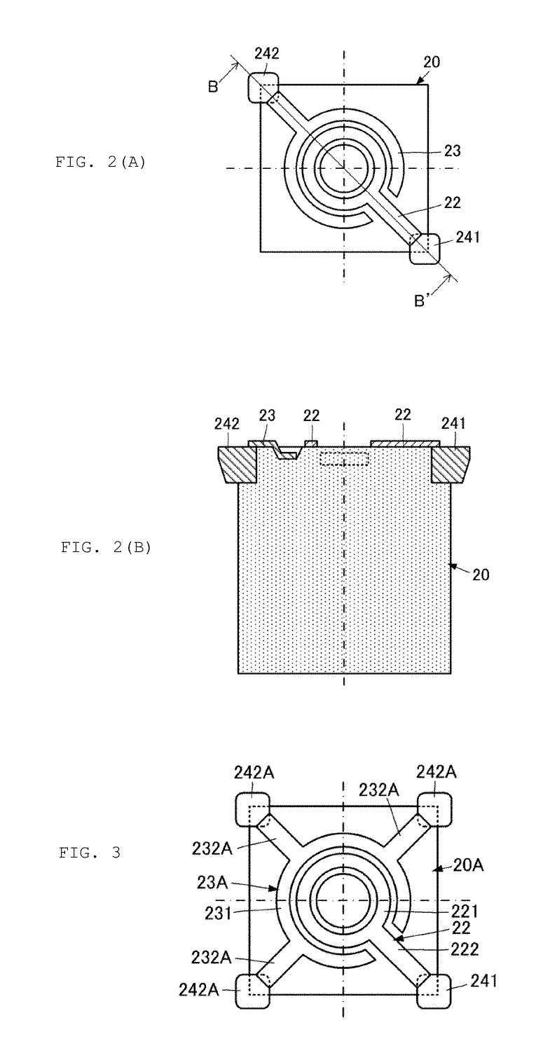

A surface emitting element which is a photoelectric conversion element according to a first exemplary embodiment will be described with reference to the drawings. FIG. 1(A) is a plan view of the surface emitting element according to the first exemplary embodiment, and FIG. 1(B) is a side sectional view of the surface emitting element according to the first exemplary embodiment. FIG. 1(B) shows a cross section taken along line A-A′ shown in FIG. 1(A). FIG. 2(A) is a plan view of a substrate of the surface emitting element according to the first exemplary embodiment, and FIG. 2(B) is a sectional view of the substrate of the surface emitting element according to the first exemplary embodiment. FIG. 2(B) shows a cross section taken along line B-B′ shown in FIG. 2(A).

As shown in FIG. 1, the surface emitting element 10 includes a substrate 20 and a casing 30.

The substrate 20 includes a first electrode 22, a second electrode 23, a first terminal electrode 241, and a second terminal electrode 242. The substrate 20 has a substantially rectangular parallelepiped shape, and is made of a semiconductor material. For example, the substrate 20 is mainly made of GaAs in an exemplary aspect. The substrate 20 is made up of a plurality of layers having different compositions along a thickness direction. When a voltage is applied to the substrate 20 by the first electrode 22 and the second electrode 23, light having a predetermined frequency is excited and resonates. A direction in which this light resonates is a thickness direction, and the resonated light is radiated (emitted) from the surface of the substrate 20 to the outside. That is, the surface of the substrate 20 is a light-emitting surface. As described above, the substrate 20 has an optical element portion having a photoelectric conversion function.

The first electrode 22 and the second electrode 23 are formed on the surface of the substrate 20. The first electrode 22 and the second electrode 23 are made of metal having high conductivity and easy for pattern forming. For example, the first electrode 22 and the second electrode 23 are made of copper, aluminum, gold or the like.

The first electrode 22 includes an annular portion 221 and a linear portion 222. The annular portion 221 of the first electrode 22 surrounds the light-emitting region of the substrate 20. The linear portion 222 of the first electrode 22 connects the annular portion 221 of the first electrode 22 and the first terminal electrode 241.

The second electrode 23 includes an annular portion 231 and a linear portion 232. The annular portion 231 of the second electrode 23 surrounds the annular portion 221 of the first electrode 22. At this time, the annular portion 231 of the second electrode 23 is disposed except for a region where the linear portion 222 of the first electrode 22 is disposed. The linear portion 232 of the second electrode 23 connects the annular portion 231 of the second electrode 23 and the second terminal electrode 242.

The first terminal electrode 241 and the second terminal electrode 242 are disposed at diagonal positions on the surface of the substrate 20. The first terminal electrode 241 and the second terminal electrode 242 are substantially rectangular parallelepipeds. The first terminal electrode 241 and the second terminal electrode 242 are made of metal having high conductivity and easy to form by plating. For example, the first terminal electrode 241 and the second terminal electrode 242 are made of copper (Cu).

One portion of each of the first terminal electrode 241 and the second terminal electrode 242 are embedded (embedded portion) in the substrate 20, and the other portion protrudes outward from the side surface of the substrate 20 (protrusion). The protrusion of the first terminal electrode 241 protrudes from both of the two orthogonal side surfaces forming the corner where the first terminal electrode 241 is disposed. The protrusion of the second terminal electrode 242 protrudes from both of the two orthogonal side surfaces forming the corner where the second terminal electrode 242 is disposed. The first terminal electrode 241 and the second terminal electrode 242 are disposed on the same plane as the surface of the substrate 20.

The first terminal electrode 241 and the second terminal electrode 242 having such shapes are formed by a semi-additive plating method and dry etching according to an exemplary aspect. Specifically, a temporary substrate is formed having an outer shape that includes the first terminal electrode 241 and the second terminal electrode 242. A hole is formed by etching a portion where the first terminal electrode 241 and the second terminal electrode 242 are formed in the temporary substrate. A seed layer is formed in the hole, and the first terminal electrode 241 and the second terminal electrode 242 are formed by plating using the seed layer. The temporary substrate is etched (dry etching) on all the side surfaces to form the substrate 20 where the first terminal electrode 241 and the second terminal electrode 242 protrude partially.

As further shown, the casing 30 includes first connection electrodes 311, 312, second connection electrodes 321, 322, wiring electrodes 331, 332, via electrodes 341, 342, a first external electrode 351, and a second external electrode 352.

The casing 30 has a substantially rectangular parallelepiped shape, and is mainly made of silicon (Si), for example. It is noted that the casing 30 may be made of another material so long as being excellent in workability such as drilling and inexpensive as compared with the substrate 20.

According to the exemplary aspect, the casing 30 is provided with a depression 301 penetrating from the front surface to the rear surface. The center of the opening surface on the surface of the depression 301 and the center of the opening surface of the rear surface substantially coincide with each other in a plan view of the depression 301. An opening area of the surface in the depression 301 is larger than an opening area of the rear surface. That is, the wall surface forming the depression 301 in the casing 30 has a tapered shape in a side view. The shape of the opening on the rear surface of the depression 301 is equal to the shape of the rear surface of the substrate 20 (identical to the shape in a plan view of the substrate 20).

The first connection electrodes 311, 312 and the second connection electrodes 321, 322 are disposed at diagonal positions of the depression 301 on the surface of the casing 30. The first connection electrodes 311, 312 and the second connection electrodes 321, 322 are substantially rectangular parallelepipeds. The first connection electrodes 311, 312 and the second connection electrodes 321, 322 are made of metal having high conductivity and easy to form by plating. For example, the first connection electrodes 311, 312 and the second connection electrodes 321, 322 are made of copper (Cu).

One portion of each of the first connection electrodes 311, 312 and the second connection electrodes 321, 322 are embedded (embedded portion) in the casing 30, and the other portions protrude from the casing 30 toward (and into) the depression 301 (protrusion). The protrusions of the first connection electrodes 311, 312 protrude from both of the two orthogonal side surfaces forming the corner where the first connection electrodes 311, 312 are disposed. The protrusions of the second connection electrodes 321, 322 protrude from both of the two orthogonal side surfaces forming the corner where the second connection electrodes 321, 322 are disposed. The first connection electrodes 311, 312 and the second connection electrodes 321, 322 are disposed on the same plane as the surface of the casing 300. Similarly to the first terminal electrode 241 and the second terminal electrode 242, the first connection electrodes 311, 312 and the second connection electrodes 321, 322 are formed by a semi-additive plating method and dry etching according to an exemplary aspect.

The wiring electrodes 331, 332 are disposed on the surface of the casing 30. The via electrodes 341, 342 have a shape penetrating the casing 300 from the front surface to the rear surface. The via electrode 341 is connected to the first connection electrodes 311, 312 via the wiring electrode 331. The via electrode 342 is connected to the second connection electrodes 321, 322 via the wiring electrode 332. By forming the via electrodes 341, 342 in the casing 30, it is possible to form the via electrodes 341, 342 with a smaller diameter than forming the via electrodes on the substrate 20. This enables reduction in the planar area for providing the via electrode.

The first external electrode 351 and the second external electrode 352 are formed on the rear surface of the casing 30. The first external electrode 351 is connected to the via electrode 341. The second external electrode 352 is connected to the via electrode 342. A bump 361 for external connection is formed on the first external electrode 351 and a bump 362 for external connection is formed on the second external electrode 352.

In such a configuration, the substrate 20 is disposed in the depression 301 of the casing 30. Preferably, the surface of the substrate 20 and the surface of the casing 30 are the same plane. The rear surface of the substrate 20 and the rear surface of the casing 30 are the same plane.

Two orthogonal side surfaces of the first terminal electrode 241 of the substrate 20 are in contact with the first connection electrodes 311, 312 of the casing 30, respectively. Two orthogonal side surfaces of the second terminal electrode 242 of the substrate 20 are in contact with the second connection electrodes 321, 322 of the casing 30, respectively. With this configuration, the first electrode 22 is connected to the first external electrode 351. The second electrode 23 is connected to the second external electrode 352. Therefore, a voltage for photoelectric conversion (for light emission in the present embodiment) can be applied to the first electrode 22 and the second electrode 23.

By using the configuration according to the exemplary embodiment, it is possible to reliably form a bump for applying a voltage from the outside while reducing the shape of the substrate 20 that emits light. At this time, it is possible to make the area of the substrate 20 smaller than the cross-sectional area of the optical fiber 90 disposed close to the substrate, which could not be achieved by the conventional configuration. The substrate 20 is formed by epitaxial growth so as to ensure characteristics, and hence the formation is very expensive. In the present application, since the substrate 20 can be made small as described above, it is possible to achieve the inexpensive surface emitting element 10 maintaining the conventional performance. Further, in the case of the configuration having a via electrode as in the present embodiment, it is possible to reduce the size of the via electrode and effectively achieve further size reduction.

Moreover, with the above-mentioned configuration where the opening shape on the rear surface side of the depression 301 and the rear surface shape of the substrate 20 are the same, the substrate 20 can be disposed at a desired position with high accuracy.

In addition, by the rear surface of the depression 301 being open, the casing 30 does not interfere with the substrate 20 and can be disposed in a desired state with high accuracy.

It is noted that in one aspect, each of the first terminal electrode 241 and the second terminal electrode 242 may have a tapered shape in which the first terminal electrode 241 and the second terminal electrode 242 taper toward the rear surface of the substrate 20. Although an aspect has been shown in the present embodiment where each of the first terminal electrode 241 and the second terminal electrode 242 has the tapered shape, each of the first connection electrodes 311, 312 and the second connection electrodes 321, 322 may have a tapered shape.

Next, a surface emitting element which is a photoelectric conversion element according to a second exemplary embodiment will be described with reference to the drawing. FIG. 3 is a plan view of a substrate of the surface emitting element according to the second exemplary embodiment.

The surface emitting element according to the present embodiment is different from the first exemplary embodiment in the configurations of a second electrode 23A and a second terminal electrode 242A.

As shown in FIG. 3, the substrate 20A includes the first electrode 22, the second electrode 23A, the first terminal electrode 241, and the second terminal electrode 242A. The second electrode 23A includes an annular portion 231 and a plurality of linear portions 232A. The plurality of linear portions 232A are disposed at angular intervals of approximately 90° in a plan view of the substrate 20A. One linear portion 232A has a shape extending in the same direction as the linear portion 222 of the first electrode 22 and the other two linear portions 232A have a shape extending in a direction orthogonal to the linear portion 222.

The number of the second terminal electrodes 242A is three. The plurality of second terminal electrodes 242A are disposed at three corners other than the corner where the first terminal electrode 241 of the substrate 20A is disposed. The plurality of terminal electrodes 242A include protrusions that protrude from the side surface of the substrate 20A. The plurality of second terminal electrodes 242A are connected to the annular portion 231 by the plurality of linear portions 232A of the second electrode 23A.

With such a configuration, terminal conductors are formed so as to protrude at all corners in the plan view of the substrate 20A. Thereby, it is possible to dispose and fix the substrate 20A in a more stable posture with respect to the casing 30. In addition, with this configuration, it is possible to reduce the resistance of the system made up of the second terminal electrode 242A and the second electrode 23A without changing the size of the surface emitting element.

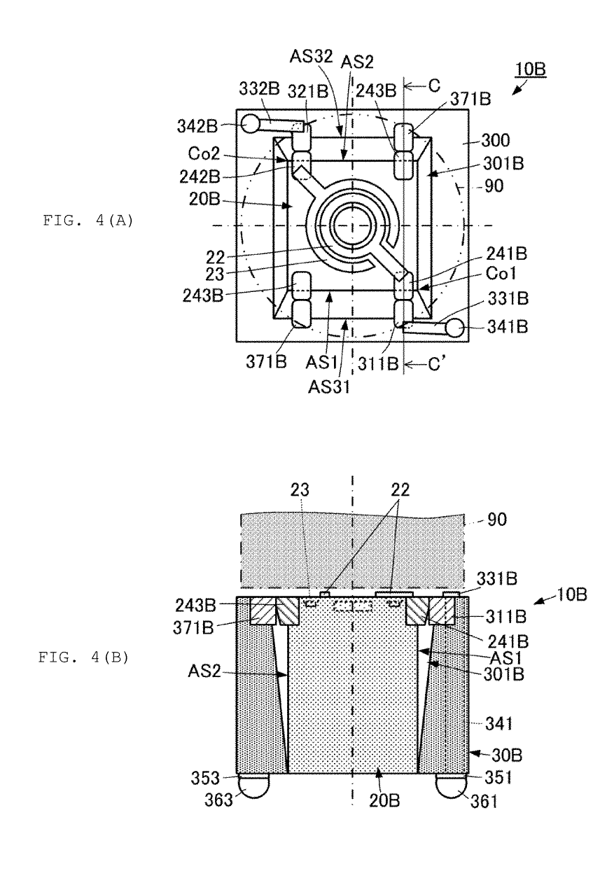

Next, a surface emitting element which is a photoelectric conversion element according to a third exemplary embodiment will be described with reference to the drawings. FIG. 4(A) is a plan view of the surface emitting element according to the third exemplary embodiment, and FIG. 4(B) is a side sectional view of the surface emitting element according to the third exemplary embodiment. FIG. 4(B) shows a cross section taken along the line C-C′ shown in FIG. 4(A).

A surface emitting element 10B according to the present embodiment is different from the surface emitting element 10 according to the first embodiment in the configuration of a terminal electrode and the configuration of a connection electrode of a casing 30B.

A substrate 20B includes the first electrode 22, the second electrode 23, a first terminal electrode 241B, a second terminal electrode 242B, and a third terminal electrode 243B. The first electrode 22 and the second electrode 23 are identical to the substrate 20 according to the first embodiment.

The first terminal electrode 241B is connected to the first electrode 22. The first terminal electrode 241B is disposed in the vicinity of a first corner Co1 in a plan view of the substrate 20B and on a first side surface AS1. The first terminal electrode 241B is disposed so as to protrude from the first side surface AS1.

The second terminal electrode 242B is connected to the second electrode 23. The second terminal electrode 242B is disposed in the vicinity of a second corner Co2 in the plan view of the substrate 20B and on a second side surface AS2. The second corner Co2 is a diagonal of the first corner Co1. The second side surface AS2 is the surface opposite to the first side surface AS1 on the substrate 20B. The second terminal electrode 242B is disposed so as to protrude from the second side surface AS2.

The third terminal electrode 243B is disposed on the first side surface AS1 and the second side surface AS2. The third terminal electrode 243B of the first side surface AS1 protrudes from the first side surface AS1. The third terminal electrode 243B of the first side surface AS1 is disposed at the end opposite to the end where the first terminal electrode 241B is disposed on the first side surface AS1. The third terminal electrode 243B of the second side surface AS2 protrudes from the second side surface AS2. The third terminal electrode 243B of the second side surface AS2 is disposed at the end opposite to the end where the second terminal electrode 242B is disposed on the second side surface AS2.

With such a configuration, there is no terminal electrode protruding from the two side surfaces of the substrate 20B and protruding from the other two side surfaces. As a result, the substrate 20B can be reduced in size. In addition, in the case of using a method of collectively forming a plurality of substrates 20B on a mother substrate and then dividing the mother substrate to produce a plurality of substrates 20B, it is possible to increase the number of substrates 20B taken from the mother substrate. Thereby, the cost of the substrate 20B can also be reduced.

The casing 30B includes a depression 301B, a first connection electrode 311B, a second connection electrode 321B, a wiring electrodes 331B, 332B, via electrodes 341B, 342B, a first external electrode 351, a second external electrode 352, and a fixing electrode 371B. The first external electrode 351 and the second external electrode 352 are identical to the casing 30 according to the first embodiment. The basic structures and functions of the depression 301B, the wiring electrodes 331B, 332B, and the via electrodes 341B, 342B are identical to the wiring electrodes 331, 332 and the via electrodes 341, 342 according to the first embodiment.

The first connection electrode 311B is disposed on a first surface AS31 forming the depression 301B of the casing 30B. The first connection electrode 311B protrudes from the first surface AS31 toward the depression 301B. The first connection electrode 311B is disposed near one end of the first surface AS31. The first connection electrode 311B is connected to the wiring electrode 331B.

The second connection electrode 321B is disposed on a second surface AS32 forming the depression 301B of the casing 30B. The second connection electrode 321B protrudes from the second surface AS32 toward the depression 301B. The second connection electrode 321B is disposed near the other end of the second surface AS32. The second connection electrode 321B is connected to the wiring electrode 332B.

The fixing electrode 371B is disposed on each of the first surface AS31 and the second surface AS32 which form the depression 301B of the casing 30B. The fixing electrode 371B protrudes from the first surface AS31 and the second surface AS32 toward the depression 301B. The fixing electrode 371B on the first surface AS31 side is disposed near the other end of the first surface AS31. The fixing electrode 371B on the second surface AS32 side is disposed near one end of the second surface AS32.

The substrate 20B is disposed in the depression 301B of the casing 30B. At this time, the first terminal electrode 241B of the substrate 20B is in contact with the first connection electrode 311B of the casing 30B. Similarly, the second terminal electrode 242B is in contact with the second connection electrode 321B. The third terminal electrode 243B is in contact with the fixing electrode 371B. With this configuration, the substrate 20B is fixed to the casing 30B.

Even with such a configuration, similar to the first exemplary embodiment, it is possible to achieve the high-performance and inexpensive surface emitting element 10B maintaining the conventional performance. Further, in the surface emitting element 10B of the present embodiment, the number of substrates 20B to be taken can be increased, and the surface emitting element 10B can be achieved at lower cost than the surface emitting element 10 according to the first embodiment.

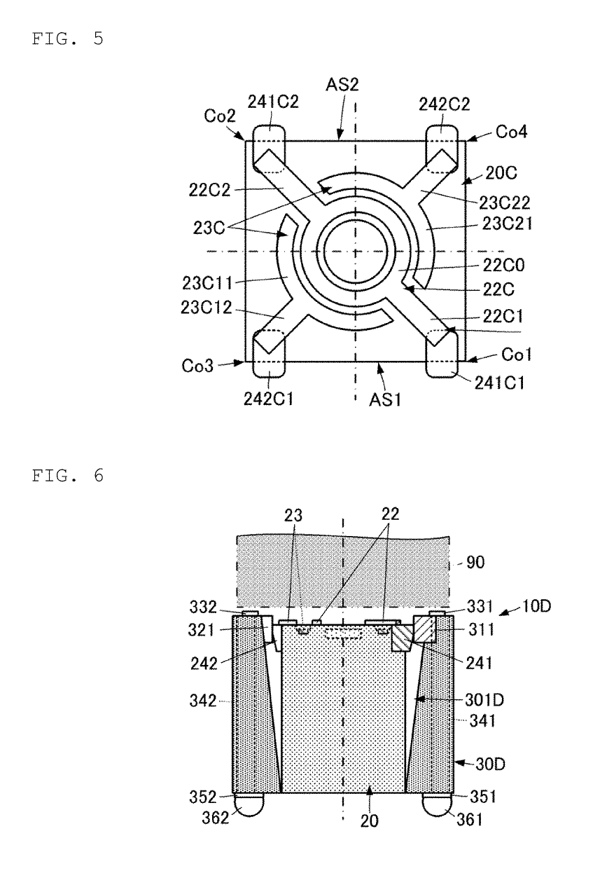

Next, a surface emitting element which is a photoelectric conversion element according to a fourth exemplary embodiment will be described with reference to the drawing. FIG. 5 is a plan view of a surface emitting element according to the fourth exemplary embodiment.

A substrate 20C of the surface emitting element according to the present embodiment is different from the substrate 20B according to the third embodiment in the shapes and placement patterns of a first electrode 22C, a second electrode 23C, first terminal electrodes 241C1, 241C2, and second terminal electrodes 242C1, 242C2.

The first electrode 22C includes an annular portion 22C0 and two linear portions 22C1, 22C2. The extending directions of the linear portions 22C1, 22C2 are the same. The connection point between the linear portion 22C1 and the annular portion 22C0 is positioned on the opposite side of the annular portion 22C0 with respect to the connection point between the linear portion 22C2 and the annular portion 22C0.

The second electrode 23C includes circular arc portions 23C11, 23C21 and linear portions 23C12 and 23C22. The circular arc portions 23C11 and 23C21 are achieved by dividing the annular shape at two positions. A linear portion 23C12 is connected to the circular arc portion 23C11. A linear portion 23C22 is connected to the circular arc portion 23C21. The extending direction of the linear portions 23C12, 23C22 is orthogonal to the extending direction of the linear portions 22C1, 22C2 of the first electrode 22C.

The first terminal electrode 241C1 is disposed in the vicinity of the first corner Co1 in a plan view of the substrate 21 and on the first side surface AS1. The first terminal electrode 241C1 is disposed so as to protrude from the first side surface AS1. The first terminal electrode 241C1 is connected to the linear portion 22C1 of the first electrode 22C. The first terminal electrode 241C2 is disposed in the vicinity of the second corner Co2 in the plan view of the substrate 21 and on the second side surface AS2. The first terminal electrode 241C2 is disposed so as to protrude from the second side surface AS2. The first terminal electrode 241C2 is connected to the linear portion 22C2 of the first electrode 22C.

In this exemplary embodiment, the first terminal electrode 241C1 and the first terminal electrode 241C2 are disposed at positions and shapes that are rotationally symmetrical by 180° in a plan view of the substrate 20C.

The second terminal electrode 242C1 is disposed in the vicinity of a third corner Co3 in the plan view of the substrate 20C and on the first side surface AS1. The third corner Co3 is a corner of the substrate 20C on the side opposite to the first corner Co1 on the first side surface AS1. The second terminal electrode 242C1 is disposed so as to protrude from the first side surface AS1. The second terminal electrode 242C1 is connected to the linear portion 23C12 of the second electrode 23C. The second terminal electrode 242C2 is disposed in the vicinity of a fourth corner Co4 in the plan view of the substrate 20C and on the second side surface AS2. The fourth corner Co4 is a corner of the substrate 20C on the side opposite to the second corner Co2 in the second side surface AS2. The second terminal electrode 242C2 is disposed so as to protrude from the second side surface AS2. The second terminal electrode 242C2 is connected to the linear portion 23C22 of the second electrode 23C.

The second terminal electrode 242C1 and the second terminal electrode 242C2 are disposed in a position and a shape that is rotationally symmetrical by 180° in the plan view of the substrate 20C.

Although not shown, the first connection electrode is disposed so as to be in contact with the first terminal electrodes 241C1 and 241C2, respectively. Further, the second connection electrode is disposed so as to be in contact with the second terminal electrodes 242C1 and 242C2, respectively.

Even with such a configuration, similarly to the surface emitting element according to the third embodiment, it is possible to achieve the high performance and inexpensive surface emitting element 10B maintaining the conventional performance.

Further, by using the configuration of the present embodiment, in any of two modes in which the substrate 20C is rotated by 180° in a plan view, it is possible to use a wiring that can supply a desired voltage to the first electrode 22C and the second electrode 23C to dispose and fix the substrate 20C on the casing.

Next, a surface emitting element which is a photoelectric conversion element according to a fifth exemplary embodiment will be described with reference to the drawing. FIG. 6 is a side sectional view of the surface emitting element according to the fifth exemplary embodiment.

A surface emitting element 10D according to the present embodiment is different in the configuration of a casing 30D from the surface emitting element 10 according to the first embodiment. The other configuration is identical to that of the surface emitting element 10 according to the first exemplary embodiment.

In this exemplary embodiment, the casing 30D is different in the thickness and depth of a depression 301D from the casing 30 according to the first embodiment. The other basic structure of the casing 30D is identical to that of the casing 30 according to the first embodiment.

A thickness dimension of the casing 30D and a depth dimension of the depression 301D are larger than a thickness dimension of the substrate 20.

The substrate 20 is accommodated in 301D so that the rear surface thereof and the rear surface of the casing 30D are the same plane. With such a configuration, the surface (light-emitting surface) of the substrate 20 is inside the depression 301D of the casing 30D. Hence the surface of the substrate 20 has a depressed shape with respect to the surface of the casing 30D.

Even with such a configuration, similarly to the surface emitting element according to the first embodiment, it is possible to achieve the high-performance and inexpensive surface emitting element 10D maintaining the conventional performance. Further, by using the configuration of the present embodiment, even when the optical fiber 90 comes into contact with the surface of the surface emitting element 10D, the optical fiber 90 does not come into contact with the surface of the substrate 20, and damage to the substrate 20 can thus be prevented.

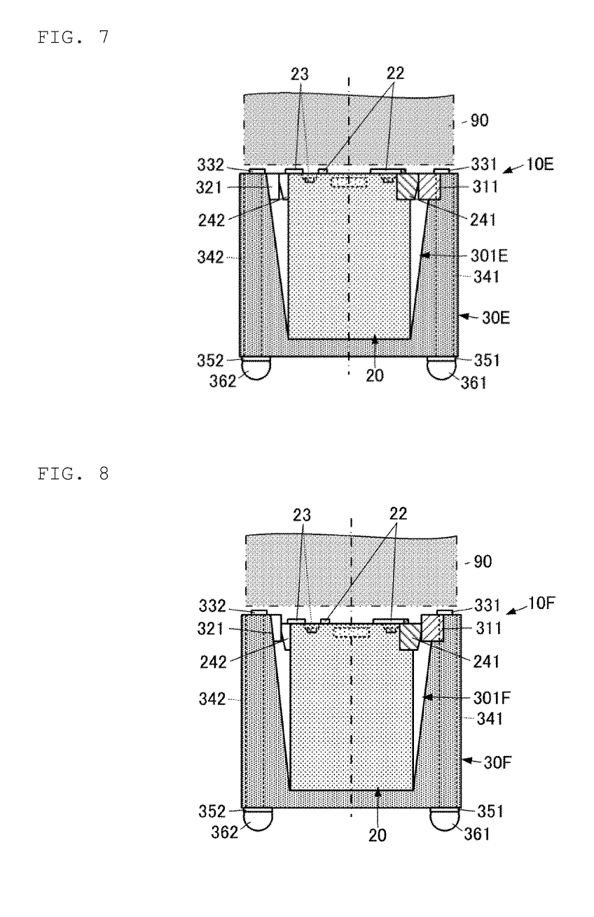

Next, a surface emitting element which is a photoelectric conversion element according to a sixth exemplary embodiment will be described with reference to the drawing. FIG. 7 is a side sectional view of the surface emitting element according to the sixth exemplary embodiment.

A surface emitting element 10E according to the present embodiment is different in the configuration of a casing 30E from the surface emitting element 10 according to the first embodiment. The other configuration is identical to that of the surface emitting element 10 according to the first embodiment.

The casing 30E is different from the casing 30 according to the first embodiment in that the bottom surface of a depression 301E does not penetrate.

The rear surface of the substrate 20 is accommodated in the depression 301E in the state of being in contact with the bottom surface of the depression 301E.

Even with such a configuration, similarly to the surface emitting element 10 according to the first embodiment, it is possible to achieve the high-performance and inexpensive surface emitting element 10E maintaining the conventional performance.

Next, a surface emitting element which is a photoelectric conversion element according to a seventh exemplary embodiment will be described with reference to the drawing. FIG. 8 is a side sectional view of the surface emitting element according to the seventh exemplary embodiment.

A surface emitting element 10F according to the present embodiment is different in the configuration of a casing 30F from the surface emitting element 10D according to the fifth embodiment. The other configuration is identical to that of the surface emitting element 10D according to the fifth embodiment.

The casing 30F is different from the casing 30D according to the fifth embodiment in that the bottom surface of a depression 301F does not penetrate.

The rear surface of the substrate 20 is accommodated in the depression 301F in the state of being in contact with the bottom surface of the depression 301F.

Even with such a configuration, similarly to the surface emitting element 10D according to the fifth embodiment, it is possible to achieve the high-performance and inexpensive surface emitting element 10F maintaining the conventional performance.

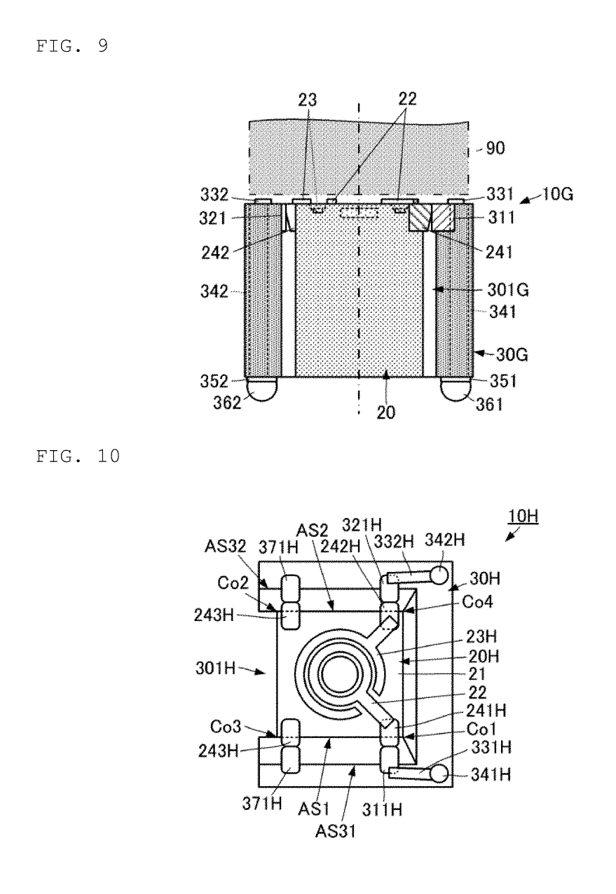

Next, a surface emitting element which is a photoelectric conversion element according to an eighth exemplary embodiment will be described with reference to the drawing. FIG. 9 is a side sectional view of the surface emitting element according to the eighth exemplary embodiment.

A surface emitting element 10G according to the present embodiment is different in the configuration of a casing 30G from the surface emitting element 10 according to the first embodiment. The other configuration is identical to that of the surface emitting element 10 according to the first embodiment.

In the casing 30G, a depression 301G does not have a tapered shape with respect to the casing 30 according to the first embodiment. Even with such a configuration, since the terminal electrode and the connection electrode are in contact with each other, the substrate 20 is accurately fixed to the casing 30G.

Even with such a configuration, similarly to the surface emitting element 10 according to the first embodiment, it is possible to achieve the high performance and inexpensive surface emitting element 10G maintaining the conventional performance.

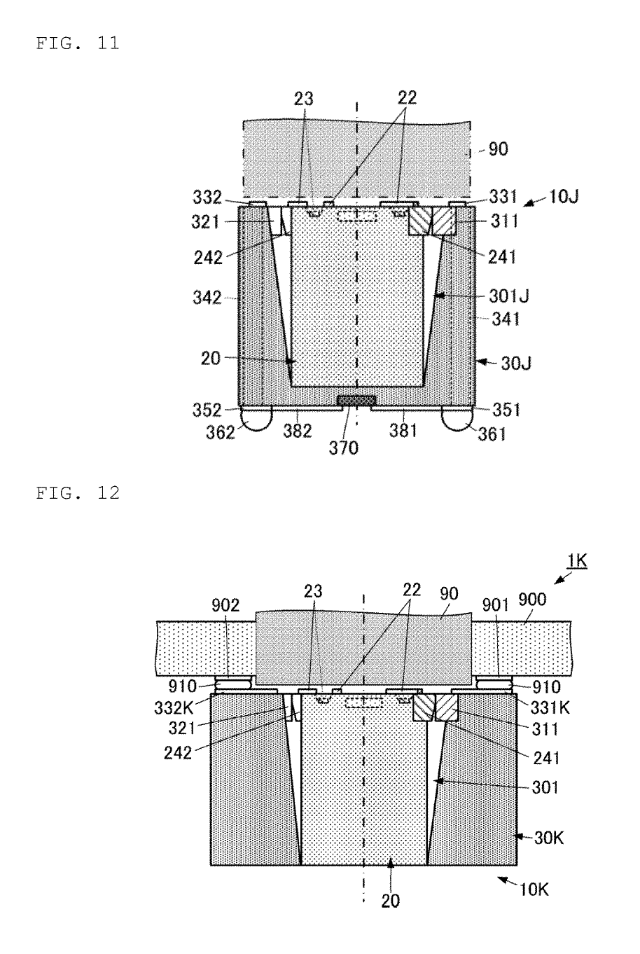

Next, a surface emitting element which is a photoelectric conversion element according to a ninth exemplary embodiment will be described with reference to the drawing. FIG. 10 is a plan view of the surface emitting element according to the ninth exemplary embodiment.

A surface emitting element 10H according to the present embodiment is different in the shape of a casing 30H from the surface emitting element 10B according to the third embodiment. Further, in accordance with the shape of this casing 30H, the surface emitting element 10H according to the present embodiment is different in the electrode pattern of a substrate 20H from the surface emitting element 10B according to the third embodiment.

The substrate 20H includes the first electrode 22, a second electrode 23H, a first terminal electrode 241H, a second terminal electrode 242H, and a third terminal electrode 243H. The first electrode 22 is identical to that of the substrate 20 according to the first embodiment. An annular part of the second electrode 23H is identical to that of the substrate 20 according to the first embodiment, and an extending direction of the linear portion is different. A linear portion of the second electrode 23H extends in a direction orthogonal to the linear portion of the first electrode 22 and extends toward the fourth corner Co4 in a plan view of the substrate 20H.

The first terminal electrode 241H is identical to the first terminal electrode 241B of the surface emitting element 10B according to the third embodiment. The first terminal electrode 241H is disposed in the vicinity of the first corner Col in the plan view of the substrate 21 and on the first side surface AS1. The first terminal electrode 241H is disposed so as to protrude from the first side surface AS1.

The second terminal electrode 242H is disposed in the vicinity of the fourth corner Co4 in the plan view of the substrate 21 and on the second side surface AS2. The fourth corner Co4 is an angle in a direction forming 90° with respect to the direction of the first corner Co1 with the center of the surface of the substrate 20H taken as a reference. The second terminal electrode 242H is disposed so as to protrude from the second side surface AS2.

The third terminal electrode 243H is disposed in the vicinity of the second corner Co2 and the third corner Co3 in the plan view of the substrate 20H. The second corner Co2 is a diagonal of the first corner Co1, and the third corner Co3 is a diagonal of the fourth corner Co4. The third terminal electrode 243H disposed at the second corner Co2 is disposed in the vicinity of the second corner Co2 in the plan view of the substrate 20H and on the second side surface AS2. The third terminal electrode 243H is disposed so as to protrude from the second side surface AS2. The third terminal electrode 243H disposed at the third corner Co3 is disposed in the vicinity of the third corner Co3 in the plan view of the substrate 20H and on the first side surface AS1. The third terminal electrode 243H is disposed so as to protrude from the first side surface AS1.

The casing 30H includes a depression 301H, a first connection electrode 311H, a second connection electrode 321H, wiring electrodes 331H, 332H, via electrodes 341H, 342H, and a fixing electrode 371H.

The depression 301H is opened on one side surface of the casing 30H. The opening is provided on the surface side orthogonal to the first surface AS31 and the second surface AS32 of the casing 30H forming the depression 301H.

The first connection electrode 311H is disposed on the first surface AS31 forming the depression 301H of the casing 30H. The first connection electrode 311H protrudes from the first surface AS31 toward the depression 301H. The first connection electrode 311H is disposed near one end of the first surface AS31 (the side opposite to the side where the depression 301H is opened). The first connection electrode 311H is connected to the wiring electrode 331H, and the wiring electrode 331H is connected to the via electrode 341H.

The second connection electrode 321H is disposed on the second surface AS32 forming the depression 301H of the casing 30H. The second connection electrode 321H protrudes from the second surface AS32 toward the depression 301. The second connection electrode 321H is disposed near one end of the second surface AS32 (the side opposite to the side where the depression 301H is opened). The second connection electrode 321H is connected to the wiring electrode 332H, and the wiring electrode 332H is connected to the via electrode 342H.

The fixing electrode 371H is disposed on the first surface AS31 and the second surface AS32 forming the depression 301H of the casing 30H, respectively. The fixing electrode 371H protrudes from the first surface AS31 and the second surface AS32 toward the depression 301H. The fixing electrode 371H on the first surface AS31 side is disposed near the other end (the side where the depression 301H is opened) of the first surface AS31. The fixing electrode 371H on the second surface AS32 side is disposed near the other end (the side where the depression 301H is opened) of the second surface AS32.

The substrate 20H is accommodated in the depression 301H of the casing 30H. In this case, the three sides of the rear surface of the substrate 20H are preferably in contact with three surfaces forming the depression 301H.

The first terminal electrode 241H of the substrate 20H is in contact with the first connection electrode 311H of the casing 30H. Similarly, the second terminal electrode 242H is in contact with the second connection electrode 321H. The third terminal electrode 243H is in contact with the fixing electrode 371H. With this configuration, the substrate 20H is fixed to the casing 30H.

Even with such a configuration, as in the third embodiment, it is possible to achieve the high-performance and inexpensive surface emitting element 10H maintaining the conventional performance.

Next, a surface emitting element which is a photoelectric conversion element according to a tenth exemplary embodiment will be described with reference to the drawing. FIG. 11 is a side sectional view of the surface emitting element according to the tenth exemplary embodiment.

A surface emitting element 10J according to the present embodiment has a configuration in which an ESD element 370 is added to the surface emitting element 10E according to the sixth embodiment. The other configuration is identical to that of the surface emitting element 10E according to the sixth embodiment.

The ESD element 370 is formed near the bottom surface of the casing 30J. The ESD element 370 is achieved by forming a Zener diode structure by performing predetermined doping on the semiconductor casing 30J. The ESD element 370 is connected to the first external electrode 351 by the wiring electrode 381 and is connected to the second external electrode 352 by the wiring electrode 382.

With this configuration, the substrate 20 of the surface emitting element 10J and the ESD element 370 are connected in parallel between the first external electrode 351 and the second external electrode 352. Thereby, the substrate 20 of the surface emitting element 10J can be protected from the external surge. In addition, with this configuration, since the ESD element 370 is formed in the casing 30J, it is possible to downsize the ESD element 370 as compared with the mode of forming the ESD element 370 and the mode of connecting the ESD element 370 separately.

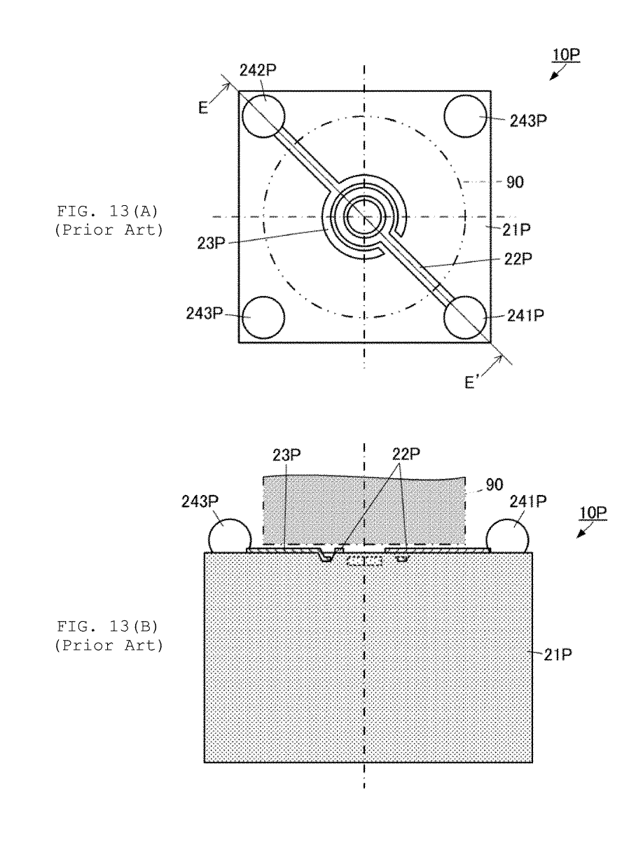

Next, an optical communication module according to an eleventh exemplary embodiment will be described with reference to the drawing. FIG. 12 is a side sectional view of the optical communication module according to the eleventh exemplary embodiment.

An optical communication module 1K includes a surface emitting element 10K, an optical fiber 90, and a fiber fixing member 900. The surface emitting element 10K is different in the structure of the casing 30K from the surface emitting element 10 according to the first embodiment. The casing 30K includes wiring electrodes 331K, 332K. The wiring electrode 331K is connected to the first connection electrode 311. The wiring electrode 332K is connected to the second connection electrode 321.

The fiber fixing member 900 is made of a material having predetermined rigidity and includes mounting electrodes 901, 902. The fiber fixing member 900 has a through hole.

The mounting electrode 901 of the fiber fixing member 900 is bonded to the wiring electrode 331 of the surface emitting element 10K by solder bumps 910. The mounting electrode 902 of the fiber fixing member 900 is bonded to the wiring electrode 332 of the surface emitting element 10K by solder bumps 910. The optical fiber 90 is fixed to the fiber fixing member 900 in the state of being inserted through the through hole of the fiber fixing member 900. One end of the optical fiber 90 is close to the surface (light-emitting surface) of the surface emitting element 10.

With such a configuration, it is possible to fix these positions in a state in which the surface emitting element 10K and the one end of the optical fiber 90 are brought close to each other. This enables achievement of the highly efficient optical communication module 1K.

### DESCRIPTION OF REFERENCE SYMBOLS

10, 10B, 10D, 10E, 10F, 10G, 10H, 10J, 10K: surface emitting element

20, 20A, 20B, 20C, 20D, 20H: substrate

22, 22C: first electrode

22C0, 221, 231: annular portion

22C1, 22C2, 22C12, 22C22, 23C12, 23C22, 222, 232: linear portion

23, 23A, 23C, 23H: second electrode

23C11, 23C21: arc portion

30, 30B, 30D, 30E, 30F, 30G, 30H, 30J, 30K: casing

90: optical fiber

241, 241B, 241C1, 241C2, 241H: first terminal electrode 242, 242A, 242B, 242C1, 242C2, 242H: second terminal electrode

243B, 243H: third terminal electrode

301, 301B, 301D, 301E, 301F, 301G, 301H: depression

311, 312, 311B, 311H: first connection electrode

321, 322, 321B, 321H: second connection electrode

331, 332, 331B, 332B, 331H, 332H, 331K, 332K: wiring electrode

341, 342, 341B, 342B, 341H, 342H: via electrode

351: first external electrode

352: second external electrode

361, 362: bump

370: ESD element

371B, 371H: fixing electrode

381, 382: wiring electrode

900: fiber fixing member

901, 902: mounting electrode

910: solder bump

1K: optical communication module

1. A photoelectric conversion element comprising:
a casing having a depression;
a semiconductor substrate disposed in the depression of the casing and including an optical element having a photoelectric conversion function, the substrate having a surface configured as one of a light-emitting surface or a light-receiving surface;
first and second terminal electrodes disposed on the substrate and protruding from respective side surfaces of the substrate; and
first and second connection electrodes disposed in the casing and protruding from the casing towards the depression,
wherein the first terminal electrode contacts the first connection electrode and the second terminal electrode contacts the second connection electrode.

2. The photoelectric conversion element according to claim 1, wherein the substrate comprises GaAs and the casing comprises silicon.

3. The photoelectric conversion element according to claim 1, wherein the depression is a through hole that penetrates from a front surface to a rear surface of the casing.

4. The photoelectric conversion element according to claim 1, wherein the depression has a tapered shape in which a planar area decreases from an opening surface toward a bottom surface of the casing, and the bottom surface of the casing has an identical planar shape to a planar shape of the substrate.

5. The photoelectric conversion element according to claim 1, wherein the depression has a depth that is greater than a thickness of the substrate.

6. The photoelectric conversion element according to claim 1, wherein the substrate is rectangle shaped in a plan view of the photoelectric conversion element, and the first and second terminal electrodes protrude only from respective side surfaces of the substrate that face each other.

7. The photoelectric conversion element according to claim 1,
wherein the substrate is rectangle shaped in a plan view of the photoelectric conversion element, and
wherein the photoelectric conversion element includes a pair of third terminal electrodes, such that the first terminal electrode, the second terminal electrode, and the pair of third terminal electrodes are disposed respectively at four corners of the surface of the substrate.

8. The photoelectric conversion element according to claim 1,
wherein the first terminal electrode comprises a pair of first terminal electrodes and the second terminal electrode comprises a pair of second terminal electrode, and
wherein the pair of first terminal electrodes are disposed on the substrate with rotational symmetry by 180°, and the second terminal electrodes are disposed on the substrate with rotational symmetry by 180°, in a plan view of the substrate.

9. The photoelectric conversion element according to claim 1, further comprising a Zener diode disposed in the casing and connected between the first external electrode and the second external electrode.

10. The photoelectric conversion element according to claim 1, wherein the first and second terminal electrodes are disposed in the substrate and protruding into the depression of the casing to contact the first and second connection electrodes, respectively.

11. The photoelectric conversion element according to claim 1, wherein the first and second terminal electrodes do not extend above the surface of the substrate.

12. The photoelectric conversion element according to claim 1, further comprising:
a pair of via electrodes extending in the casing and in contact with the first and second connection electrodes, respectively; and
a pair of external electrical contacts disposed on a surface of the casing opposite the surface of the substrate and in contact with the pair of via electrode, respectively.

13. An optical communication module, comprising:
a photoelectric conversion element including:
a casing having a depression,
a semiconductor substrate disposed in the depression of the casing and including an optical element having a photoelectric conversion function, the substrate having a surface configured as one of a light-emitting surface or a light-receiving surface;
first and second terminal electrodes disposed on the substrate and protruding from respective side surfaces of the substrate; and
first and second connection electrodes disposed in the casing and protruding from the casing towards the depression,
wherein the first terminal electrode contacts the first connection electrode and the second terminal electrode contacts the second connection electrode;
an optical fiber having one end of a light guide path facing the surface of the substrate;
a fiber fixing member that includes a through hole, through which the optical fiber is inserted, and fixes the optical fiber,
wherein the fiber fixing member is bonded to the photoelectric conversion element.

14. The optical communication module according to claim 13, wherein a plane of surface of the substrate is smaller than a diameter of the optical fiber.

15. A photoelectric conversion element comprising:
a casing having a depression;
a semiconductor substrate disposed in the depression of the casing;
first and second terminal electrodes disposed in at least one side surface of the substrate and protruding into the depression of the casing; and
first and second connection electrodes disposed in the casing and protruding into the depression to contact the first and second terminal electrodes, respectively.

16. The photoelectric conversion element according to claim 15, wherein the semiconductor substrate includes an optical element having a photoelectric conversion function and a surface configured as one of a light-emitting surface or a light-receiving surface.

17. The photoelectric conversion element according to claim 15, wherein the depression has a tapered shape in which a planar area decreases from an opening surface toward a bottom surface of the casing, and the bottom surface of the casing has an identical planar shape to a planar shape of the substrate.

18. The photoelectric conversion element according to claim 15,
wherein the substrate is rectangle shaped in a plan view of the photoelectric conversion element, and
wherein the photoelectric conversion element includes a pair of third terminal electrodes, such that the first terminal electrode, the second terminal electrode, and the pair of third terminal electrodes are disposed respectively at four corners of the surface of the substrate.

19. The photoelectric conversion element according to claim 15,
wherein the first terminal electrode comprises a pair of first terminal electrodes and the second terminal electrode comprises a pair of second terminal electrode, and
wherein the pair of first terminal electrodes are disposed in the substrate with rotational symmetry by 180°, and the second terminal electrodes are disposed in the substrate with rotational symmetry by 180°, in a plan view of the substrate.

20. The photoelectric conversion element according to claim 15, wherein the first and second terminal electrodes do not extend above a top surface of the substrate.
